(19) United States
(12) Patent Application Publication
(10) Pub. No.: US 2025/0087624 A1
(43) Pub. Date: Mar. 13, 2025

(54) SEMICONDUCTOR CHIP BONDING APPARATUS AND SEMICONDUCTOR PACKAGE MANUFACTURING APPARATUS

(71) Applicant: SAMSUNG ELECTRONICS CO., LTD., Suwon-si (KR)

(72) Inventors: Jing Cheng LIN, Suwon-si (KR); Sungjin Han, Suwon-si (KR); Gyeongjae JO, Suwon-si (KR); Hyunchul JUNG, Suwon-si (KR); Youngkun JEE, Suwon-si (KR)

(73) Assignee: SAMSUNG ELECTRONICS CO., LTD., Suwon-Si (KR)

(21) Appl. No.: 18/611,241

(22) Filed: Mar. 20, 2024

(30) Foreign Application Priority Data
Sep. 12, 2023 (KR) 10-2023-0121345

(51) Int. Cl. H01L 23/00

(52) U.S. Cl. CPC H01L 24/74; H01L 2224/74; H01L 2924/40

(57) ABSTRACT

A semiconductor package manufacturing apparatus is provided and includes a bonding head including at least one vacuum hole, and at least one adsorption trench in a lower surface of the bonding head and connected to the at least one vacuum hole. A lower part of the bonding head includes at least one first portion, and a second portion spaced apart from the at least one first portion and surrounding the at least one first portion in a plan view. The at least one adsorption trench is defined by and between the at least one first portion and the second portion, and at least a portion of an inner surface of the at least one adsorption trench and at least a portion of an outer surface of the at least one adsorption trench are curved in the plan view.

### CROSS-REFERENCE TO RELATED APPLICATION

This application is based on and claims priority under 35 U.S.C. § 119 to Korean Patent Application No. 10-2023-0121345, filed on Sep. 12, 2023, in the Korean Intellectual Property Office, the disclosure of which is incorporated by reference herein in its entirety.

### BACKGROUND

### 1. Field

Embodiments of the present disclosure relate to a semiconductor package manufacturing apparatus and a semiconductor package manufacturing method using the same, and more particularly, to a semiconductor chip bonding apparatus and a method of bonding semiconductor chips using the same.

### 2. Description of Related Art

Due to increased performance of electronic products, semiconductor packages containing stacked semiconductor chips are being used. Accordingly, a bonding process may be necessary to stack semiconductor chips and electrically connect the semiconductor chips to each other. The bonding process for semiconductor chips may be performed in various ways. Damage to semiconductor chips may occur during the bonding process of semiconductor chips.

### SUMMARY

Embodiments of the present disclosure provide a semiconductor chip bonding apparatus and a semiconductor package manufacturing apparatus that prevent damage to semiconductor chips.

Embodiments of the present disclosure relate to a semiconductor chip bonding apparatus and a semiconductor package manufacturing apparatus.

According to embodiments of the present disclosure, a semiconductor package manufacturing apparatus is provided and includes a bonding head including at least one vacuum hole, and at least one adsorption trench in a lower surface of the bonding head and connected to the at least one vacuum hole. A lower part of the bonding head includes at least one first portion, and a second portion spaced apart from the at least one first portion and surrounding the at least one first portion in a plan view. The at least one adsorption trench is defined by and between the at least one first portion and the second portion, and at least a portion of an inner surface of the at least one adsorption trench and at least a portion of an outer surface of the at least one adsorption trench are curved in the plan view.

According to embodiments of the present disclosure, a semiconductor package manufacturing apparatus is provided and includes a bonding head including: an upper bonding head that includes a placement guide portion; a lower bonding head on a lower surface of the upper bonding head and having a smaller width than a width of the upper bonding head; a vacuum hole passing through the upper bonding head and a portion of the lower bonding head; and an adsorption trench in a lower surface of the lower bonding head and connected to the vacuum hole, wherein at least a portion of an outer surface of the adsorption trench has a curved shape in a plan view, and wherein the adsorption trench is in an edge area of the lower surface of the lower bonding head.

According to embodiments of the present disclosure, a semiconductor package manufacturing apparatus is provided and including a bonding head including: an upper bonding head including a notch portion; a lower bonding head on a lower surface of the upper bonding head, having a smaller width than a width of the upper bonding head, and including a material that is different from a material of the upper bonding head; a vacuum hole passing through the upper bonding head and extending into the lower bonding head; and an adsorption trench connected to the vacuum hole and passing through a lower surface of the lower bonding head. The vacuum hole includes: an upper vacuum hole having a first diameter; and a lower vacuum hole between the upper vacuum hole and the adsorption trench and having a second diameter that is less than the first diameter. A lower part of the lower bonding head includes: a first portion; and a second portion spaced apart from the first portion and surrounding the first portion in a plan view, and wherein the adsorption trench is defined by and between the first portion and the second portion, and an inner surface and an outer surface of the adsorption trench have a curved shape.

### BRIEF DESCRIPTION OF DRAWINGS

Embodiments will be more clearly understood from the following detailed description taken in conjunction with the accompanying drawings in which:

FIG. 1A is a plan view of a semiconductor package manufacturing apparatus according to some embodiments;

FIG. 1B is a cross-sectional view taken along line I-II of the semiconductor package manufacturing apparatus of FIG. 1A;

FIG. 1C is an enlarged view of area III of the semiconductor package manufacturing apparatus of FIG. 1A;

FIG. 2A is a plan view of a lower surface of a lower bonding head for explaining an adsorption trench according to an embodiment;

FIG. 2B is a plan view of a lower surface of a lower bonding head for explaining an adsorption trench according to an embodiment;

FIGS. 2C to 2I are plan views of a lower surface of a lower bonding head for explaining an adsorption trench according to some embodiments;

FIG. 3 is a diagram of a semiconductor package manufacturing apparatus according to some embodiments;

FIG. 4 is a diagram of a semiconductor package manufacturing apparatus according to some embodiments;

FIGS. 5A to 5F are diagrams for explaining a semiconductor package manufacturing method according to some embodiments;

FIGS. 6A to 6C are diagrams for explaining a semiconductor package manufacturing method according to some embodiments;

FIGS. 7A to 7E are diagrams for explaining a semiconductor package manufacturing method according to some embodiments; and

FIG. 8 is a diagram of a semiconductor package according to some embodiments.

### DETAILED DESCRIPTION

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

The same reference numerals herein may refer to the same elements throughout. Hereinafter, a semiconductor package manufacturing apparatuses and semiconductor package manufacturing methods using the same are described, according to non-limiting example embodiments of the present disclosure.

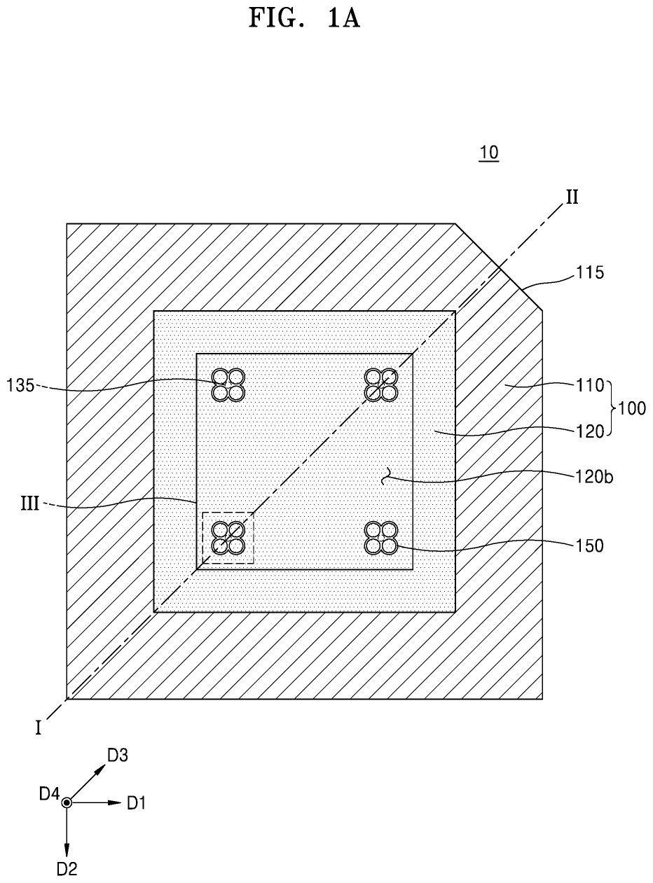

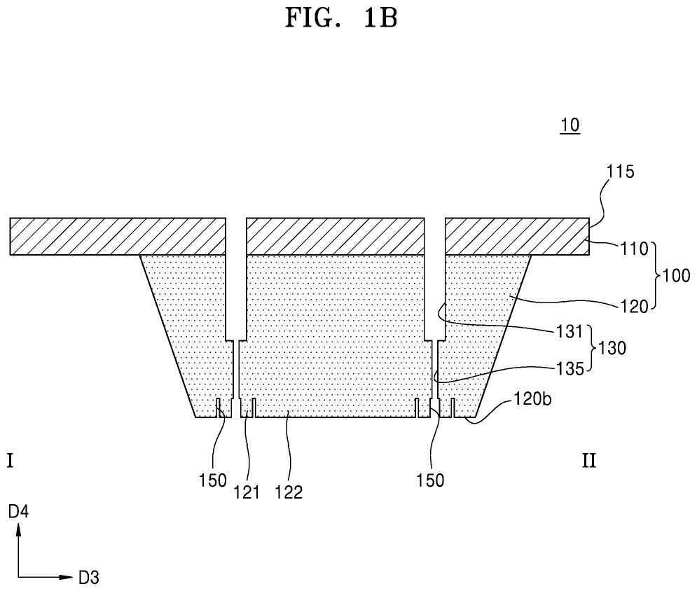

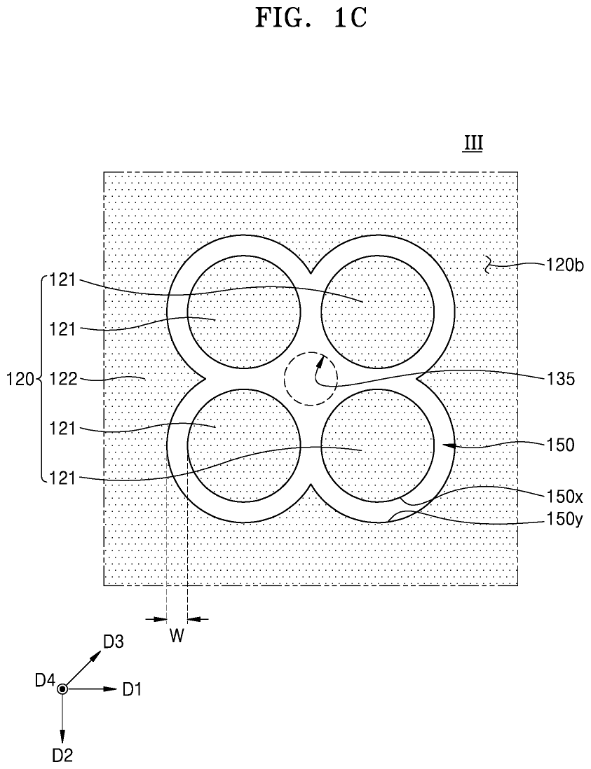

FIG. 1A is a plan view of a semiconductor package manufacturing apparatus according to some embodiments. FIG. 1B is a cross-sectional view taken along line I-II of the semiconductor package manufacturing apparatus of FIG. 1A. FIG. 1C is an enlarged view of area III of the semiconductor package manufacturing apparatus of FIG. 1A.

Referring to FIGS. 1A, 1B, and 1C, a semiconductor package manufacturing apparatus 10 may include a bonding head 100. According to embodiments, the semiconductor package manufacturing apparatus 10 may further include a bonding body, and the bonding body may be provided on an upper surface of the bonding head 100. The semiconductor package manufacturing apparatus 10 may be a semiconductor chip bonding apparatus. For example, the semiconductor package manufacturing apparatus 10 may be used to bond semiconductor chips to one another.

The bonding head 100 may include an upper bonding head 110 and a lower bonding head 120. The upper bonding head 110 may be relatively hard. The upper bonding head 110 may include metal or metal alloy. For example, the upper bonding head 110 may include stainless steel (SUS). Accordingly, the lower bonding head 120 may be stably fixed to the upper bonding head 110. An upper surface of the upper bonding head 110 may correspond to the upper surface of the bonding head 100.

The upper bonding head 110 may have a placement guide portion 115. The placement guide portion 115 may include a notch portion. In a plan view, both ends of the notch portion may be connected to two sides of the upper bonding head 110. For example, a corner portion of the upper bonding head 110 may be removed to form the notch portion. The corner portion of the upper bonding head 110 may be a portion where two adjacent sides of the upper bonding head 110 meet. During the process of manufacturing semiconductor packages, the placement guide portion 115 may provide information about the position or direction of the bonding head 100. Alternatively, the placement guide portion 115 may be a marking or engraving formed on the upper bonding head 110.

A first direction D1 may be parallel to the upper surface of the upper bonding head 110. A second direction D2 may be parallel to the upper surface of the upper bonding head 110 and may cross the first direction D1. A third direction D3 may be parallel to the upper surface of the upper bonding head 110 and may cross the first direction D1 and the second direction D2. The third direction D3 may be a diagonal direction. A fourth direction D4 may be substantially perpendicular to the first direction D1, the second direction D2, and the third direction D3. The fourth direction D4 may be a vertical direction. In a plan view, one side of the upper bonding head 110 may be parallel to the first direction D1.

The lower bonding head 120 may be provided on a lower surface of the upper bonding head 110. A lower surface 120b of the lower bonding head 120 may be configured to contact the semiconductor chip. A width of an upper surface of the lower bonding head 120 may be less than a width of the upper bonding head 110, and a length of the upper surface of the lower bonding head 120 may be less than a length of the upper bonding head 110. A width of a certain component may be measured in a direction parallel to the first direction D1, and a length of a certain component may be measured in a direction parallel to the second direction D2. A width of the upper surface of the lower bonding head 120 may be greater than a width of the lower surface 120b of the lower bonding head 120, and a length of the upper surface of the lower bonding head 120 may be greater than a length of the lower surface 120b of the lower bonding head 120. The lower surface 120b of the upper bonding head 120 may correspond to a lower surface of the bonding head 100. The lower bonding head 120 may include a polymer such as silicone rubber. The lower bonding head 120 may have a modulus of about 2.625 MPa to about 5 MPa.

The bonding head 100 may have a vacuum hole 130 and an adsorption trench 150. The vacuum hole 130 may pass through at least a portion of the bonding head 100. For example, the vacuum hole 130 may pass through the upper bonding head 110 and a portion of the lower bonding head 120. The vacuum hole 130 may extend in the vertical direction. The “vertical direction” may refer to a direction parallel to the fourth direction D4.

The vacuum hole 130 may include an upper vacuum hole 131 and a lower vacuum hole 135. The upper vacuum hole 131 may be provided in the upper bonding head 110 and an upper part of the lower bonding head 120. The upper vacuum hole 131 may have a first diameter. The lower vacuum hole 135 may be connected to the upper vacuum hole 131 and may be provided in the lower bonding head 120. The lower vacuum hole 135 may have a second diameter. The second diameter may be less than the first diameter. When only a single vacuum hole having the relatively small second diameter is formed, it may be difficult to pass through the lower bonding head 120. According to some embodiments, since the bonding head 100 has the upper vacuum hole 131 and the lower vacuum hole 135, the process of manufacturing the vacuum hole 130 may be facilitated. The vacuum hole 130 may be connected to a vacuum pump. During the operation of the semiconductor package manufacturing apparatus 10, the vacuum hole 130 may be provided in a vacuum state by the vacuum pump.

The adsorption trench 150 may be provided in a lower part of the lower bonding head 120. For example, the adsorption trench 150 may be provided in the lower surface 120b of the lower bonding head 120. The adsorption trench 150 may pass through the lower surface 120b of the lower bonding head 120. A lower part of the adsorption trench 150 may be open toward external space. The lower vacuum hole 135 may be provided between the adsorption trench 150 and the upper vacuum hole 131. In a plan view, at least a portion of the adsorption trench 150 may overlap the vacuum hole 130. For example, in a plan view, a portion of the adsorption trench 150 may overlap the lower vacuum hole 135. Accordingly, the adsorption trench 150 may be spatially connected to the vacuum hole 130. Vacuum pressure may be applied to the vacuum hole 130 through the vacuum pump, and the vacuum pressure may be provided to the adsorption trench 150. The bonding head 100 may suction the semiconductor chip using the adsorption trench 150. In a plan view, another portion of the adsorption trench 150 may be spaced apart from the lower vacuum hole 135. Accordingly, the vacuum pressure applied to the vacuum hole 130 may be distributed to the adsorption trench 150.

As shown in FIG. 1A, the vacuum hole 130 and the adsorption trench 150 may overlap an edge area of the lower surface 120b of the lower bonding head 120 in a plan view. The lower surface 120b of the lower bonding head 120 may have a center area and an edge area. The edge area of the lower surface 120b of the lower bonding head 120 may surround the central area thereof. The edge area of the lower surface 120b of the lower bonding head 120 may be provided between the center area and sidewalls of the lower bonding head 120.

A plurality of vacuum holes 130 may be provided, and a plurality of adsorption trenches 150 (also referred to as suction trenches) may be provided. The plurality of vacuum holes 130 may be laterally spaced apart from each other. The adsorption trenches 150 may be laterally spaced apart from each other. Accordingly, the adsorption trenches 150 may be connected to the vacuum holes 130, respectively.

Hereinafter, the adsorption trench 150 is described in detail with reference to FIG. 1C in a plan view. To simplify the description, a single vacuum hole 130 and a single adsorption trench 150 is described below.

The adsorption trench 150 may be a slit trench. For example, the adsorption trench 150 may have a slit shape in a plan view. The lower part of the lower bonding head 120 may have a first portion 121 and a second portion 122. The lower part of the lower bonding head 120 may include the lower surface 120b of the lower bonding head 120. The first portion 121 of the lower bonding head 120 may have a curved shape, such as a circle or an oval in a plan view. In a plan view, the second portion 122 of the lower bonding head 120 may be spaced apart from the first portion 121 of the lower bonding head 120 and may surround the first portion 121 of the lower bonding head 120. The adsorption trench 150 may be provided between the first portion 121 and the second portion 122 of the lower bonding head 120. Accordingly, the adsorption trench 150 may have a slit shape in a plan view.

The adsorption trench 150 may have a curved or rounded shape. For example, the adsorption trench 150 may have an inner surface 150x and an outer surface 150y. At least a portion of the inner surface 150x of the adsorption trench 150 may have a curved shape. The inner surface 150x of the adsorption trench 150 may correspond to an outer surface of the first portion 121 of the lower bonding head 120. The outer surface 150y of the adsorption trench 150 may face the inner surface 150x thereof. At least a portion of the outer surface 150y of the adsorption trench 150 may have a curved shape. The outer surface 150y of the adsorption trench 150 may have a shape corresponding to the inner surface 150x thereof. For example, the outer surface 150y of the adsorption trench 150 may have a similar shape to at least a portion of the corresponding inner surface 150x of the adsorption trench 150. The outer surface 150y of the adsorption trench 150 may correspond to an inner surface of the second portion 122 of the lower bonding head 120. A gap W between the inner surface 150x and the outer surface 150y of the adsorption trench 150 may be about 50 μm to about 150 μm. The gap W between the inner surface 150x and the outer surface 150y of the adsorption trench 150 may correspond to a width of the adsorption trench 150. The adsorption trench 150 may not have an angled portion in a plan view, and the angled portion of the adsorption trench 150 may be a portion where a straight line meets a straight line.

A plurality of first portions 121 of the lower bonding head 120 may be provided. Some of the first portions 121 of the lower bonding head 120 may be provided adjacent to each other. For example, the second portion 122 may not be positioned between the adjacent first portions 121 of the lower bonding head 120. The adsorption trench 150 may extend between the adjacent first portions 121 of the lower bonding head 120. Referring to FIGS. 1A and 1C, four first portions 121 of the lower bonding head 120 are adjacent to each other, and the adsorption trench 150 is further provided between the adjacent first portions 121, but embodiments of the present disclosure are not limited thereto. The number of adjacent first portions 121 of the lower bonding head 120 may vary.

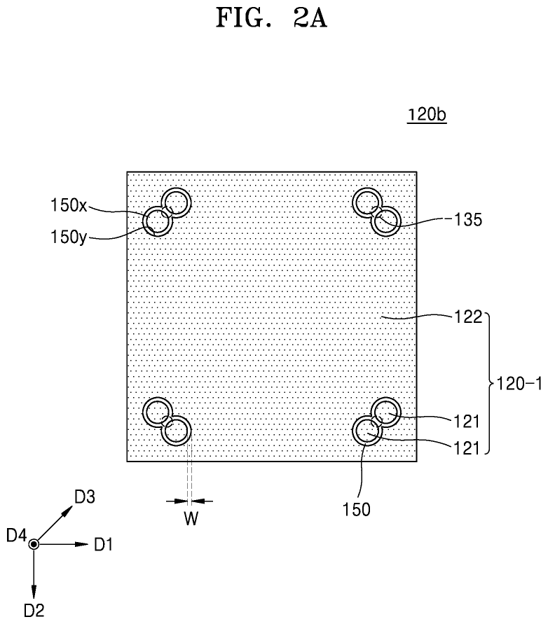

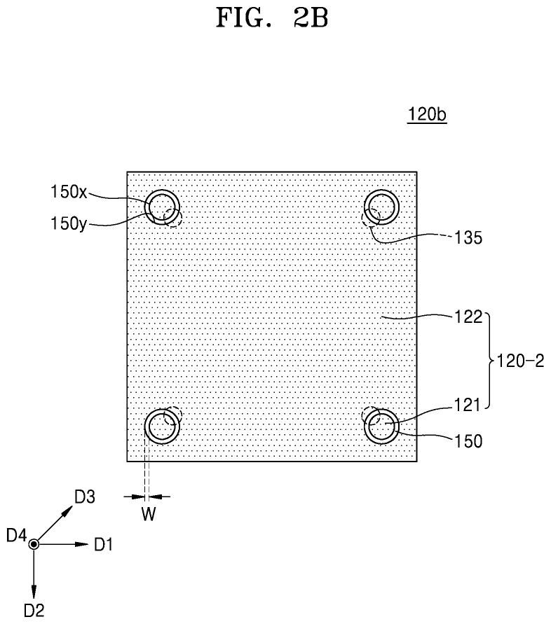

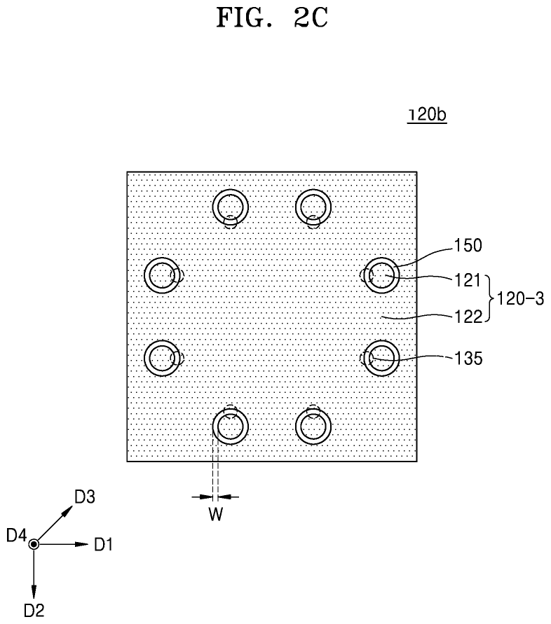

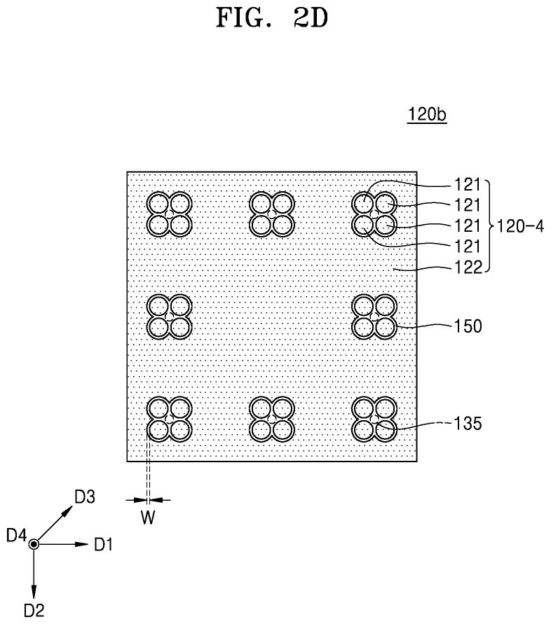

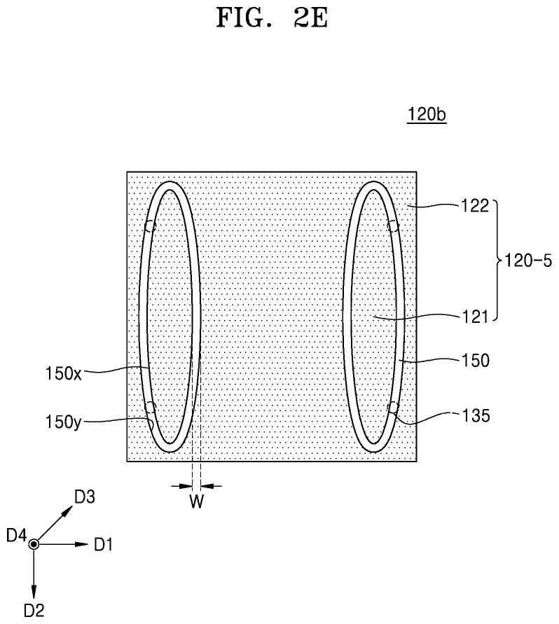

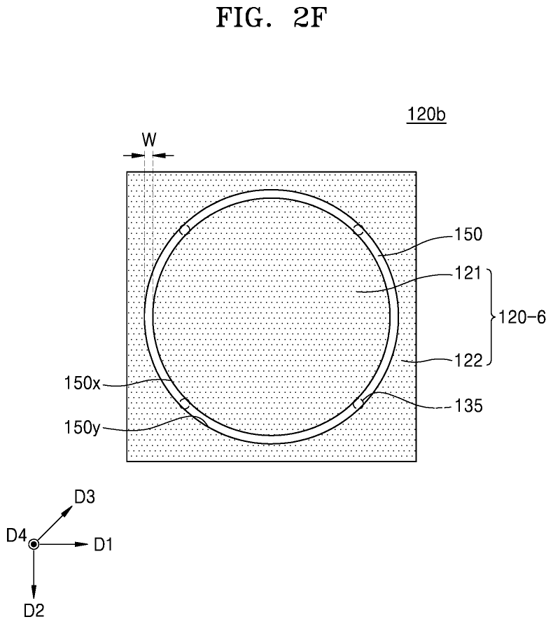

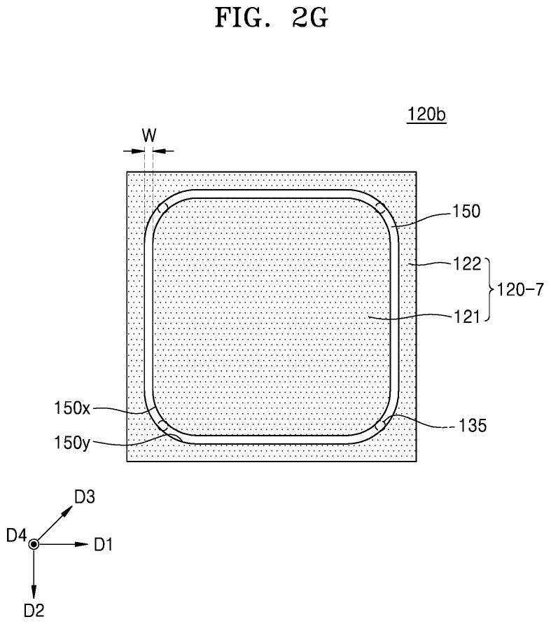

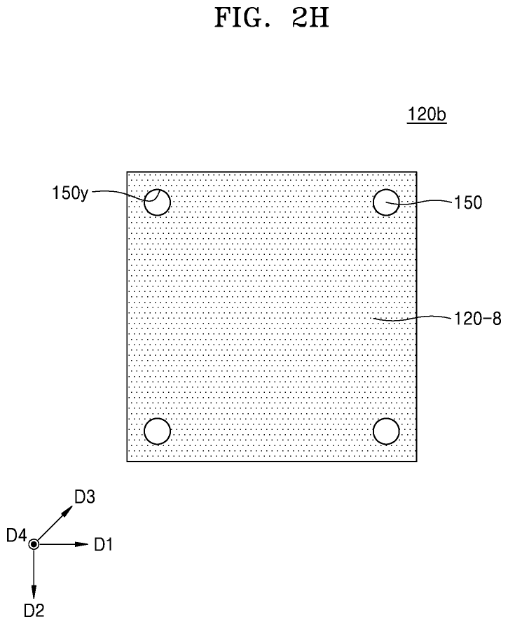

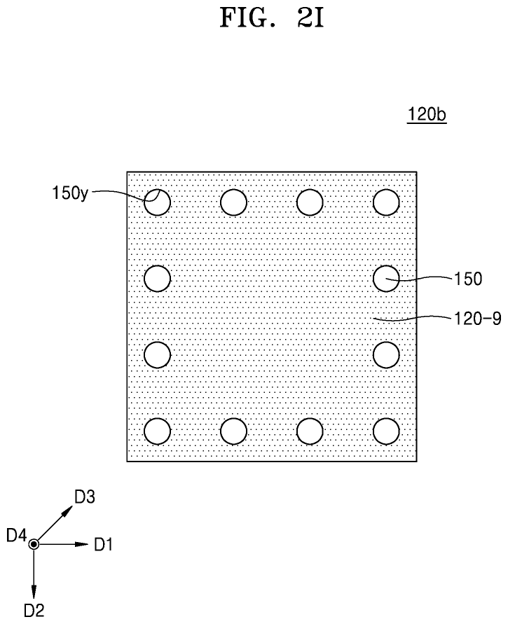

FIG. 2A is a plan view of a lower surface of a lower bonding head 120-1 for explaining an adsorption trench according to an embodiment. Hereinafter, descriptions that are substantially the same as those previously given may not be repeated, and description is made with reference to FIG. 1B.

Referring to FIG. 2A, the adsorption trench 150 may be a slit trench. Two of the first portions 121 of the lower bonding head 120 may be provided adjacent to each other. The inner surface of the second portion 122 of the lower bonding head 120-1 may have a shape corresponding to a shape of the first portions 121. The adsorption trench 150 may be provided between the adjacent first portions 121 and the second portion 122 of the lower bonding head 120-1. The adsorption trench 150 may further extend between the two adjacent first portions 121 of the lower bonding head 120-1. The outer surface 150y of the adsorption trench 150 may have, for example, a snowman shape or a dumbbell shape (e.g., a shape of a figure eight). At least a portion of the adsorption trench 150 may overlap the lower vacuum hole 135 in a plan view.

FIG. 2B is a plan view of a lower surface of a lower bonding head 120-2 for explaining an adsorption trench according to an embodiment.

Referring to FIG. 2B, the adsorption trench 150 may be a slit trench. The adsorption trench 150 may be provided between any one of the first portions 121 and the second portion 122 of the lower bonding head 120-2. Unlike FIGS. 1C and 2A, the first portions 121 of the lower bonding head 120-2 may not be adjacent to each other. For example, the second portion 122 of the lower bonding head 120 may be provided between the first portions 121 of the lower bonding head 120 to surround each of the first portions 121 of the lower bonding head 120. The adsorption trench 150 may have a closed loop or donut shape in a plan view. At least a portion of the adsorption trench 150 may overlap the lower vacuum hole 135 in a plan view.

FIGS. 2C to 2I are plan views of a lower surface of a lower bonding head 120-3, 120-4, 120-5, 120-6, 120-7, 120-8, and 120-9, respectively for explaining an adsorption trench according to some embodiments.

Referring to FIGS. 2C to 2E, the number of adsorption trenches 150 may vary. As shown in FIG. 2C, the lower bonding head 120-3 may have eight adsorption trenches 150. The planar shape of each of the adsorption trenches 150 may be the same as described with reference to FIG. 2B, but is not limited thereto.

As shown in FIG. 2D, the lower bonding head 120-4 may have nine adsorption trenches 150. The planar shape of each of the adsorption trenches 150 may be the same as described with reference to FIGS. 1A and 1C.

As shown in FIG. 2E, the lower bonding head 120-5 may have two adsorption trenches 150. Each of the adsorption trenches 150 may have an oval planar shape. For example, each of the inner surface 150x and the outer surface 150y of the adsorption trench 150 may have an oval shape. The planar shapes of the adsorption trenches 150 in FIG. 2C to 2E may be modified in various ways.

FIG. 2F is a plan view of a lower surface of a lower bonding head 120-6 for explaining an adsorption trench according to an embodiment. FIG. 2G is a plan view of a lower surface of a lower bonding head 120-7 for explaining an adsorption trench according to an embodiment.

Referring to FIGS. 2F and 2G, the lower bonding head 120-6 and the lower bonding head 120-7 may have a single adsorption trench 150. The adsorption trench 150 may be a slit trench. A single first portion 121 of the lower bonding head 120-6 (or the lower bonding head 120-7) may be provided. The adsorption trench 150 may overlap at least one lower vacuum hole 135 in a plan view.

As shown in FIG. 2F, the adsorption trench 150 may have a closed loop or donut shape in a plan view. Each of the inner surface 150x and the outer surface 150y of the adsorption trench 150 may have a circular or oval shape.

As shown in FIG. 2G, at least a portion of the inner surface 150x of the adsorption trench 150 may have a curved shape. At least a portion of the outer surface 150y of the adsorption trench 150 may have a curved shape. For example, each of the inner surface 150x and the outer surface 150y of the adsorption trench 150 may have a polygonal shape with rounded corners. For example, each of the inner surface 150x and the outer surface 150y of the adsorption trench 150 may have a square shape with rounded corners in a plan view. According to other example embodiments, each of the inner surface 150x and the outer surface 150y of the adsorption trench 150 may have a hexagonal shape with rounded corners or an octagonal shape with rounded corners.

FIG. 2H is a plan view of a lower surface of a lower bonding head 120-8 for explaining an adsorption trench according to an embodiment. FIG. 2I is a plan view of a lower surface of a lower bonding head 120-9 for explaining an adsorption trench according to an embodiment.

Referring to FIGS. 2H and 2I, the outer surface of the adsorption trench 150 may have a curved shape such as a circle or an oval. However, the lower bonding head 120-8 and the lower bonding head 120-9) may not have the first portion 121 described with reference to FIGS. 1C to 2G. The adsorption trench 150 may have a hollow hole shape. The lower bonding head 120-8 may have four adsorption trenches 150 as shown in FIG. 2H or the lower bonding head 120-9 may have twelve adsorption trenches 150 as shown in FIG. 2I. The number of adsorption trenches 150 may vary.

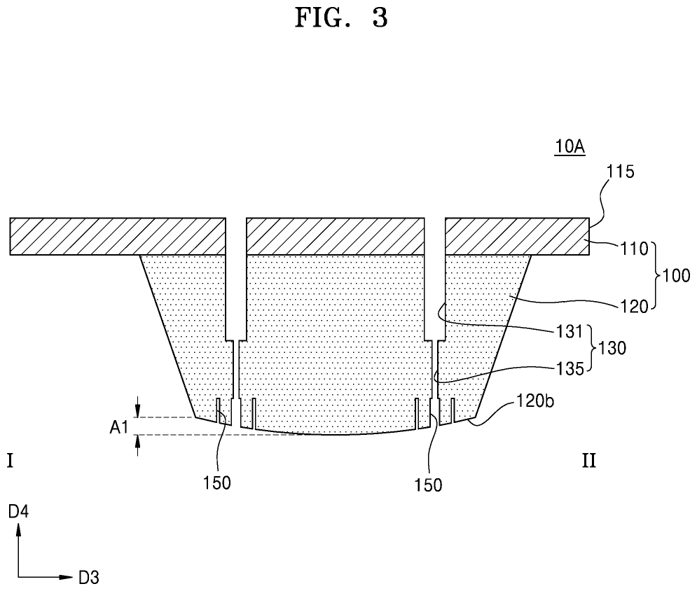

FIG. 3 is a diagram of a semiconductor package manufacturing apparatus according to some embodiments, corresponding to a cross-sectional view taken along line I-II of FIG. 1A.

Referring to FIG. 3 together with FIG. 1A, a semiconductor package manufacturing apparatus 10A may include the upper bonding head 110 and the lower bonding head 120. The lower surface 120b of the lower bonding head 120 may have a curvature. For example, the lower surface 120b of the lower bonding head 120 may have a downward convex shape. The center area of the lower surface 120b of the lower bonding head 120 may be provided at a lower level than the edge area thereof. The level of a certain component may refer to a vertical level. A level difference A1 between lowermost and uppermost parts of the lower surface 120b of the lower bonding head 120 may be about 50 μm to about 150 μm. The lowermost part of the lower surface 120b of the lower bonding head 120 may be provided on the center area of the lower surface 120b of the lower bonding head 120, and the uppermost part of the lower surface 120b of the lower bonding head 120 may be provided on the edge area of the lower surface 120b of the lower bonding head 120.

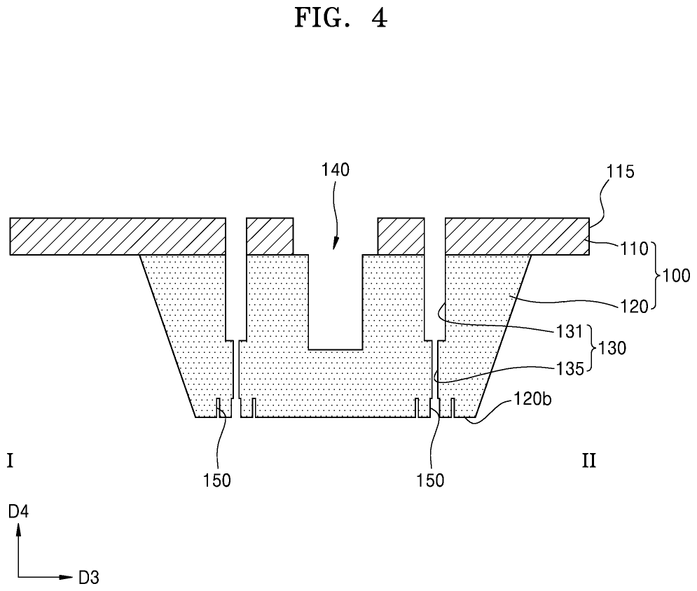

FIG. 4 is a diagram of a semiconductor package manufacturing apparatus according to some embodiments, corresponding to a cross-sectional view taken along line I-II of FIG. 1A.

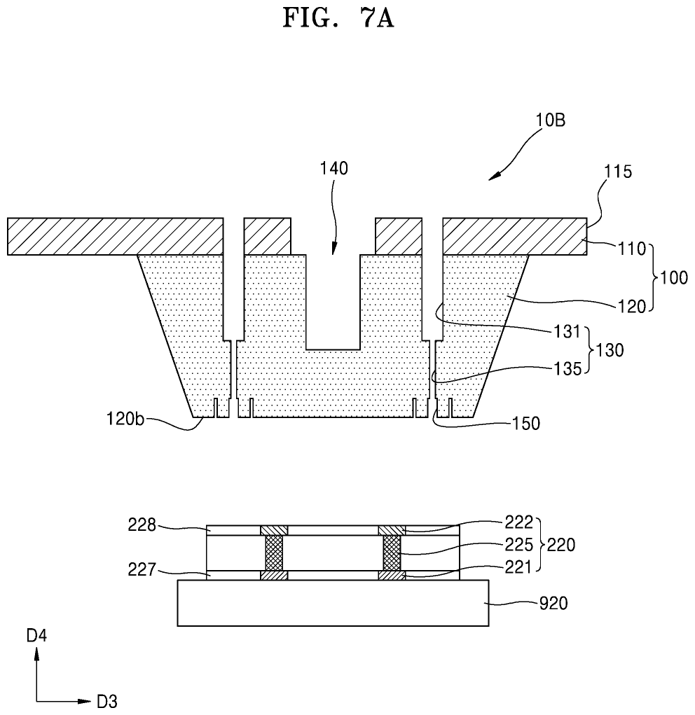

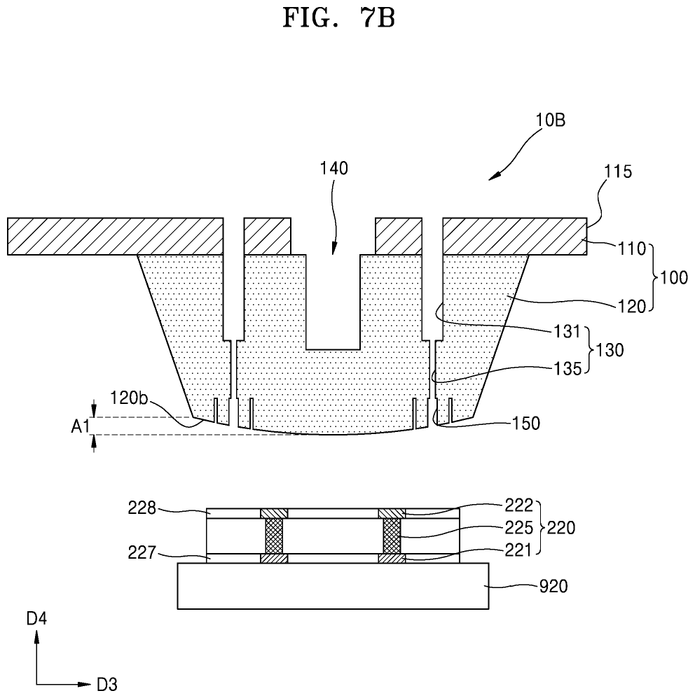

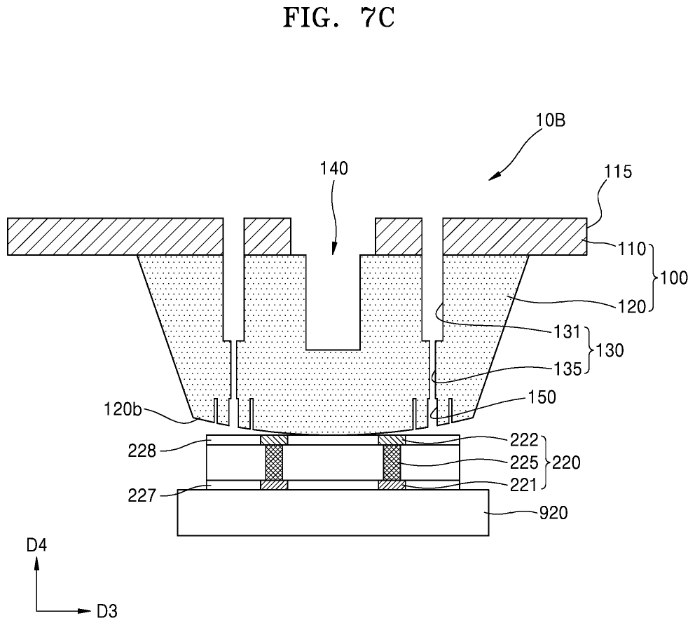

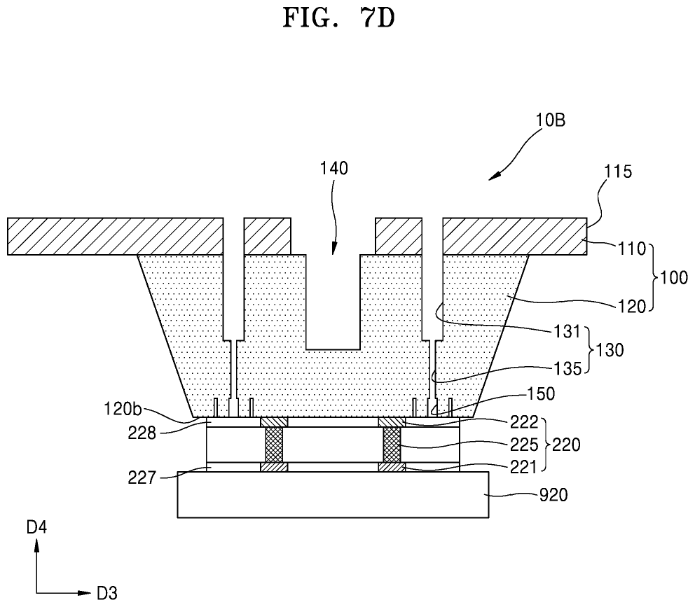

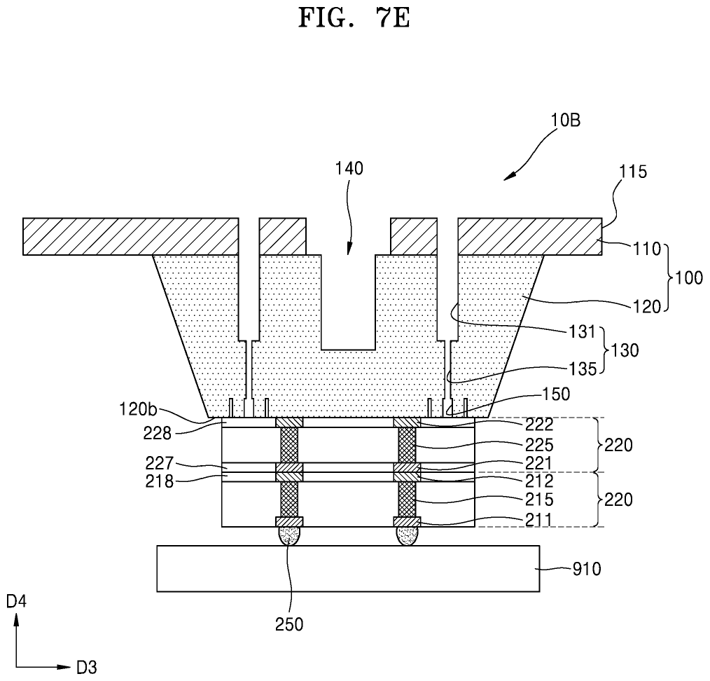

Referring to FIG. 4 together with FIG. 1A, a semiconductor package manufacturing apparatus 10B may include the bonding head 100. The bonding head 100 may have an air hole 140. The air hole 140 may be provided in the upper bonding head 110 and an upper part of the lower bonding head 120. However, the air hole 140 may be spaced apart from the lower surface 120b of the lower bonding head 120 and may not pass through the lower surface 120b of the lower bonding head 120. The air hole 140 may overlap the center area of the bonding head 100 in a plan view. For example, the air hole 140 may overlap the center area of the lower surface 120b of the lower bonding head 120 in a plan view. The air hole 140 may be laterally spaced apart from the vacuum holes 130. As an example, the air hole 140 may be positioned between the vacuum holes 130. The air hole 140 may be spaced apart from the adsorption trench 150. When the semiconductor package manufacturing apparatus 10B operates, pneumatic pressure may be applied to the air hole 140. The pneumatic pressure may refer to pressure caused by compressed air. The pneumatic pressure may be different from the vacuum pressure applied to the vacuum holes 130. As described below with reference to FIG. 7B, the shape of the lower surface 120b of the lower bonding head 120 may be deformed by the pneumatic pressure.

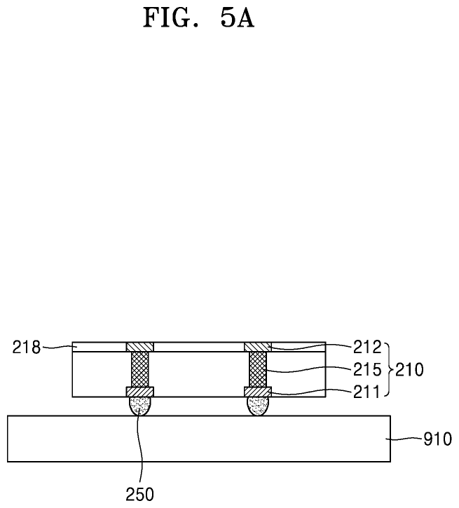

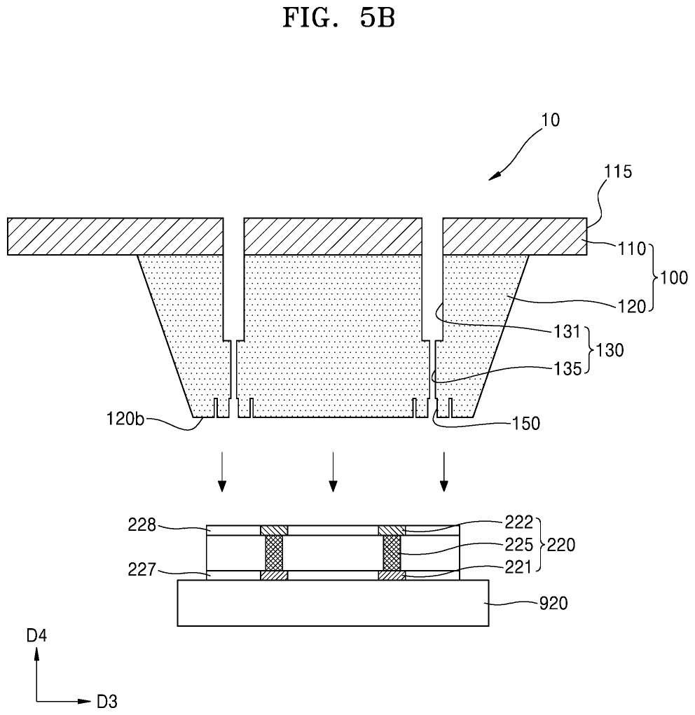

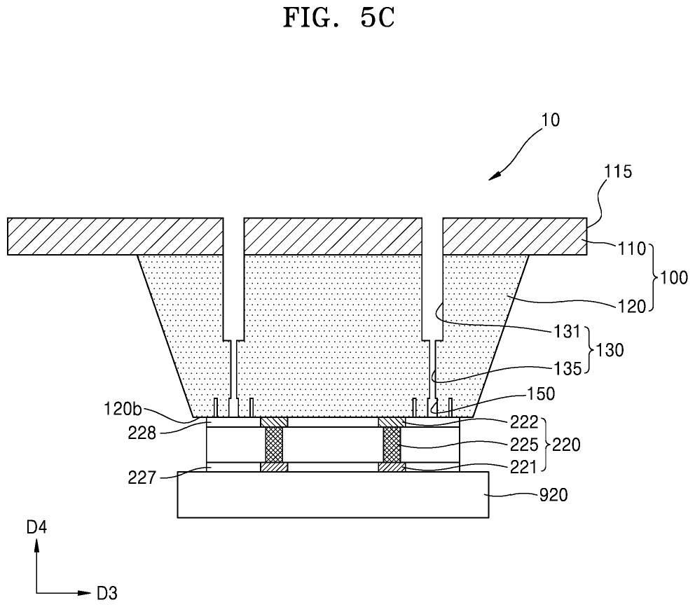

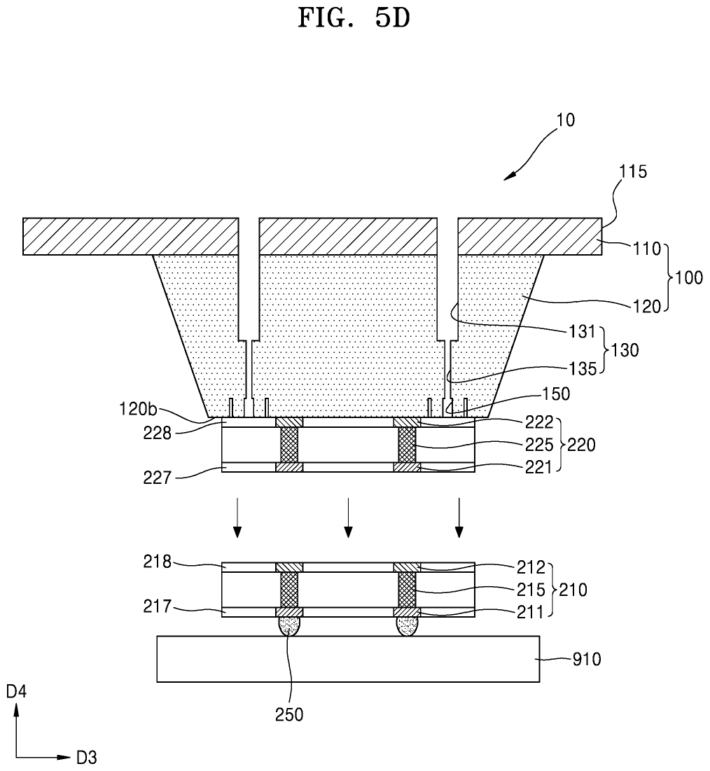

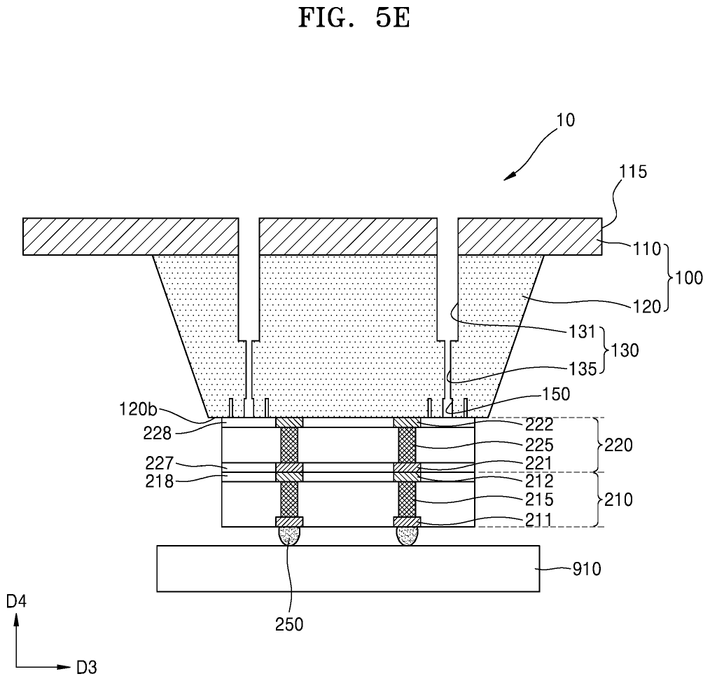

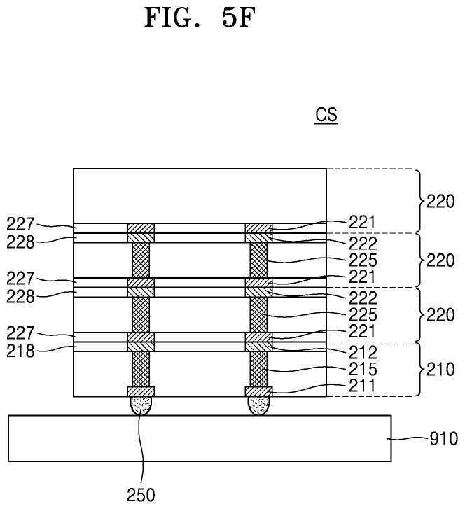

FIGS. 5A to 5F are diagrams for explaining a semiconductor package manufacturing method according to some embodiments.

Referring to FIG. 5A, a first semiconductor chip 210 may be provided on a first stage 910. The first semiconductor chip 210 may be a memory chip such as a high bandwidth memory (HBM) chip. The first semiconductor chip 210 may include first integrated circuits, a first lower pad 211, a first through via 215, a first upper pad 212, and a first upper insulating layer 218. The first integrated circuits may be provided within the first semiconductor chip 210. The first lower pad 211 and the first upper pad 212 may be provided on a lower surface and an upper surface of the first semiconductor chip 210, respectively. The first through via 215 may be provided in the first semiconductor chip 210 and may be connected to the first lower pad 211 and the first upper pad 212. The first upper pad 212 may be connected to the first lower pad 211 through the first through via 215. The first lower pad 211, the first upper pad 212, and the first through via 215 may be connected to the first integrated circuits. The first lower pad 211, the first upper pad 212, and the first through via 215 may include a conductive material such as metal. For example, the first lower pad 211, first upper pad 212, and first through via 215 may include copper, aluminum, tungsten, and/or titanium. The first upper insulating layer 218 may cover sidewalls of the first upper pad 212 and expose an upper surface of the first upper pad 212. The first upper insulating layer 218 may include a silicon-containing insulating material or a polymer. The silicon-containing insulating material may include silicon oxide, silicon nitride, silicon oxynitride, silicon carbide oxide, and/or silicon carbonitride. The upper surface of the first semiconductor chip 210 may include the upper surface of the first upper pad 212 and the upper surface of the first upper insulating layer 218.

Solder bumps 250 may be provided on a lower surface of the first lower pad 211. The solder bumps 250 may include solder material. The solder material may include a metal material that is different from the first lower pad 211, the first upper pad 212, and the first through via 215. For example, the solder material may include tin (Sn), silver (Ag), zinc (Zn), and/or alloys thereof.

Referring to FIG. 5B, a second semiconductor chip 220 may be provided on a second stage 920. The second semiconductor chip 220 may be in a state of waiting for transfer and mounting. The second semiconductor chip 220 may be a memory chip such as an HBM chip. The second semiconductor chip 220 may include second integrated circuits, a second lower pad 221, a second through via 225, a second upper pad 222, a second lower insulating layer 227, and a second upper insulating layer 228. The second semiconductor chip 220 may be the same type of chip as the first semiconductor chip 210. The second lower pad 221, the second through via 225, the second upper pad 222, the second upper insulating layer 228, and the second integrated circuits may be substantially the same as the first lower pad 211, the first through via 215, the first upper pad 212, the first upper insulating layer 218, and the first integrated circuits described with reference to FIG. 5A, respectively. An upper surface of the second semiconductor chip 220 may include an upper surface of the first upper pad 222 and an upper surface of the first upper insulating layer 228. The second lower insulating layer 227 may cover sidewalls of the second lower pad 221 and expose a lower surface of the second lower pad 221. A lower surface of the second semiconductor chip 220 may include a lower surface of the second lower pad 221 and a lower surface of the second lower insulating layer 227.

The semiconductor package manufacturing apparatus 10 may be provided on the second semiconductor chip 220. The lower surface 120b of the lower bonding head 120 may face the upper surface of the second semiconductor chip 220. The position of the bonding head 100 may be adjusted using the information about the position and direction thereof provided by the placement guide portion 115. For example, the bonding head 100 may be arranged such that the lower bonding head 120 overlaps the second semiconductor chip 220. Accordingly, the accuracy of the bonding head 100 placement may be improved, and the accuracy of the semiconductor package manufacturing process may be improved.

The width of the lower surface 120b of the lower bonding head 120 may be equal to or greater than a width of the second semiconductor chip 220, and the length of the lower surface 120b of the lower bonding head 120 may be equal to or greater than a length of the second semiconductor chip 220. Accordingly, the semiconductor package manufacturing apparatus 10 may more easily hold and suction the second semiconductor chip 220.

Afterwards, the semiconductor package manufacturing apparatus 10 may move downward toward the second semiconductor chip 220.

Referring to FIG. 5C, when the semiconductor package manufacturing apparatus 10 moves downward, the vacuum pump may operate to apply vacuum pressure to the vacuum hole 130. Since the adsorption trench 150 is connected to the vacuum hole 130, the vacuum pressure may be applied to the adsorption trench 150. The suction force may be applied to an upper surface of the second semiconductor chip 220 by the vacuum pressure. Accordingly, the lower surface 120b of the lower bonding head 120 may contact the upper surface of the second semiconductor chip 220.

As the semiconductor package manufacturing apparatus 10 that suctions the second semiconductor chip 220 moves upward, the second semiconductor chip 220 may be separated from the second stage 920.

Referring to FIG. 5D, the semiconductor package manufacturing apparatus 10 may move along with the second semiconductor chip 220 onto the upper surface of the first semiconductor chip 210. The semiconductor package manufacturing apparatus 10 may be substantially the same as described with reference to FIGS. 1A and 1B. The position of the bonding head 100 may be controlled (e.g., by a controller, comprising at least one process, of the semiconductor package manufacturing apparatus 10) using the information about the position and direction thereof provided by the placement guide portion 115. For example, the position of the bonding head 100 may be controlled (e.g., by the controller) so that the second semiconductor chip 220 is vertically aligned with the first semiconductor chip 210. The second lower pad 221 may be vertically aligned with the first upper pad 212.

Referring to FIGS. 5D and 5E in turn, as the semiconductor package manufacturing apparatus 10 moves downward, the lower surface of the second semiconductor chip 220 may contact the upper surface of the first semiconductor chip 210. A first bonding process may be performed on the second semiconductor chip 220 and the first semiconductor chip 210. Performing the first bonding process may include applying force (e.g., pressure) to the second semiconductor chip 220 using the semiconductor package manufacturing apparatus 10. As an example, the semiconductor package manufacturing apparatus 10 may further include a heater. In this case, during the first bonding process, additional heat may be applied to the second semiconductor chip 220 using the semiconductor package manufacturing apparatus 10. As an example, the first bonding process may be a pre-bonding process. Through the first bonding process, the second lower pad 221 may be primarily bonded to the first upper pad 212, and the second lower insulating layer 227 may be primarily bonded to the first upper insulating layer 218. The semiconductor package manufacturing apparatus 10 may fix the position of the second semiconductor chip 220 during the first bonding process. The semiconductor package manufacturing apparatus 10 may prevent unwanted movement of the second semiconductor chip 220 or the first semiconductor chip 210 during the first bonding process. Accordingly, the second lower pad 221 may be strongly bonded to the first upper pad 212.

According to a comparative embodiment, when the adsorption trench 150 is omitted and the vacuum hole 130 extends to the lower surface 120b of the lower bonding head 120, pressure (e.g., vacuum pressure) may concentrate on a portion of the second semiconductor chip 220. The portion of the second semiconductor chip 220 may contact the vacuum hole 130. In this case, the portion of the second semiconductor chip 220 may be damaged. For example, the shape of the second semiconductor chip 220 may be deformed. As an example, the portion of the second semiconductor chip 220 may be convexly curved to form a void. When the vacuum hole 130 has a polygonal shape, such as a square, pressure may further concentrate on a portion of the second semiconductor chip 220. At this time, the portion of the second semiconductor chip 220 may contact the corner of the vacuum hole 130 or may be adjacent to the corner of the vacuum hole 130 in a plan view.

According to some embodiments, since the bonding head 100 has the adsorption trench 150, the pressure applied to the vacuum hole 130 may be distributed along the adsorption trench 150. Accordingly, the pressure may be prevented from concentrating on a portion of the second semiconductor chip 220. According to some embodiments, the adsorption trench 150 may have a curved shape as described with reference to FIGS. 1C and 2A to 2I and may not have angled corners. Accordingly, the pressure of the adsorption trench 150 may be further prevented from concentrating on a portion of the second semiconductor chip 220. After the first bonding process is completed, the shape of the second semiconductor chip 220 may be well maintained. Accordingly, the manufacturing yield of semiconductor packages may be improved.

As shown in FIGS. 1C and 2A to 2G, the gap W between the inner surface 150x and the outer surface 150y of the adsorption trench 150 may be about 50 μm to about 150 μm. Since the gap W between the inner surface 150x and the outer surface 150y of the adsorption trench 150 is 50 μm or more, the second semiconductor chip 220 may be strongly suctioned to the lower surface 120b of the lower bonding head 120 by the vacuum pressure applied to the adsorption trench 150. Since the gap W between the inner surface 150x and the outer surface 150y of the adsorption trench 150 is 150 μm or less, damage to the second semiconductor chip 220 due to the vacuum pressure applied to the adsorption trench 150 may be prevented.

Referring again to FIG. 5E, when the first bonding process is completed, the vacuum pressure within the vacuum hole 130 and the adsorption trench 150 may be removed. Accordingly, the suction force applied to the second semiconductor chip 220 through the adsorption trench 150 can be removed. Afterwards, the semiconductor package manufacturing apparatus 10 may move upward, and the lower bonding head 120 may be spaced apart from the second semiconductor chip 220.

Referring to FIG. 5F, the first bonding process and the stacking of the second semiconductor chip 220 may be performed using the semiconductor package manufacturing apparatus (e.g., the semiconductor package manufacturing apparatus 10 in FIGS. 1A and 1B, and 5B to 5E). The first bonding process and the stacking of the second semiconductor chip 220 may be performed by substantially the same method as described with reference to FIGS. 5B to 5E. Accordingly, a plurality of second semiconductor chips 220 may be formed on the first semiconductor chip 210. Adjacent second semiconductor chips 220 may include a second lower semiconductor chip and a second upper semiconductor chip, and the second lower semiconductor chip may be pre-bonded to the second upper semiconductor chip. The first bonding process between the second semiconductor chips 220 may include primarily bonding the second lower pad 221 of the second upper semiconductor chip with the second upper pad 222 of the second lower semiconductor chip, and primarily bonding the second lower insulating layer 227 of the second upper semiconductor chip with the second upper insulating layer 228 of the first upper semiconductor chip. The semiconductor package manufacturing apparatus 10 may stably fix the position of the second upper semiconductor chip during the first bonding process.

According to some embodiments, a second bonding process may be further performed on the first semiconductor chip 210 and the second semiconductor chips 220. Performing the second bonding process may include applying heat and pressure to the first semiconductor chip 210 and the second semiconductor chips 220. When the second bonding process is completed, the first semiconductor chip 210 may be directly bonded to the lowermost second semiconductor chip 220. The direct bonding of any two chips may include hybrid bonding. The direct bonding of two chips may include directly bonding conductive components of the two chips facing each other and directly bonding insulating components of the two chips facing each other. The direct bonding of insulating components may include forming a chemical bond between the insulating components. For example, the second lower pad 221 of the second lowermost semiconductor chip 220 may be directly bonded to the first upper pad 212. Accordingly, the second semiconductor chip 220 may be electrically connected to the first semiconductor chip 210. During the second bonding process, metal atoms in the second lower pad 221 may diffuse into the first upper pad 212, and metal atoms in the first upper pad 212 may diffuse into the second lower pad 221. The interface between the first upper pad 212 and the second lower pad 221 of the lowermost second semiconductor chip 220 may not be distinguished. When two components are electrically connected to each other herein, the components are connected directly or indirectly through another conductive component. Being electrically connected to a semiconductor chip may refer to being electrically connected to integrated circuits within the semiconductor chip.

The second lower insulating layer 227 of the lowermost second semiconductor chip 220 may be directly bonded to the first upper insulating layer 218. The second lower insulating layer 227 of the lowermost second semiconductor chip 220 may be in direct contact with the first upper insulating layer 218, and a chemical bond, such as a covalent bond, may be formed between the second lower insulating layer 227 of the second lowermost semiconductor chip 220 and the first upper insulating layer 218. The second lower insulating layer 227 of the lowermost second semiconductor chip 220 may be strongly fixed to the first upper insulating layer 218 by the chemical bond. The second lower insulating layer 227 of the second semiconductor chip 220 may be connected to the first upper insulating layer 218 without an interface.

When the second bonding process is completed, adjacent second semiconductor chips 220 may be directly bonded to each other. For example, the second upper pad 222 and the second lower pad 221 of adjacent second semiconductor chips 220 may be directly bonded to each other. Since the second upper pad 222 and the second lower pad 221 of adjacent second semiconductor chips 220 are bonded, the second semiconductor chips 220 may be electrically connected to each other.

The second upper insulating layer 228 and the second lower insulating layer 227 of adjacent second semiconductor chips 220 may be directly bonded to each other. The second upper insulating layer 228 and the second lower insulating layer 227 of adjacent second semiconductor chips 220 facing each other may be in direct contact with each other. A chemical bond, such as a covalent bond, may be formed between the second upper insulating layer 228 and the second lower insulating layer 227 of adjacent second semiconductor chips 220 facing each other.

Alternatively, the second bonding process may be omitted. In this case, adjacent second semiconductor chips 220 may be directly bonded to each other when the first bonding process between the second semiconductor chips 220 is completed. Likewise, when the first bonding process between the first semiconductor chip 210 and the second semiconductor chip 220 of FIG. 5E is completed, the first semiconductor chip 210 may be directly bonded to the lowermost second semiconductor chip 220.

According to the examples described above, a chip stack CS may be manufactured. The chip stack CS may include a first semiconductor chip 210 and stacked second semiconductor chips 220. The chip stack CS may further include the solder bumps 250. The second semiconductor chips 220 may be semiconductor chips of the same type. The second uppermost semiconductor chip 220 may not include the second through via 225, the second upper pad 222, and the second upper insulating layer 228. The uppermost second semiconductor chip 220 may have a greater thickness than thicknesses of the other second semiconductor chips 220. The number of stacked second semiconductor chips 220 may vary without being limited to the example embodiment shown in FIG. 5F. For example, the chip stack CS may include a single second semiconductor chip 220.

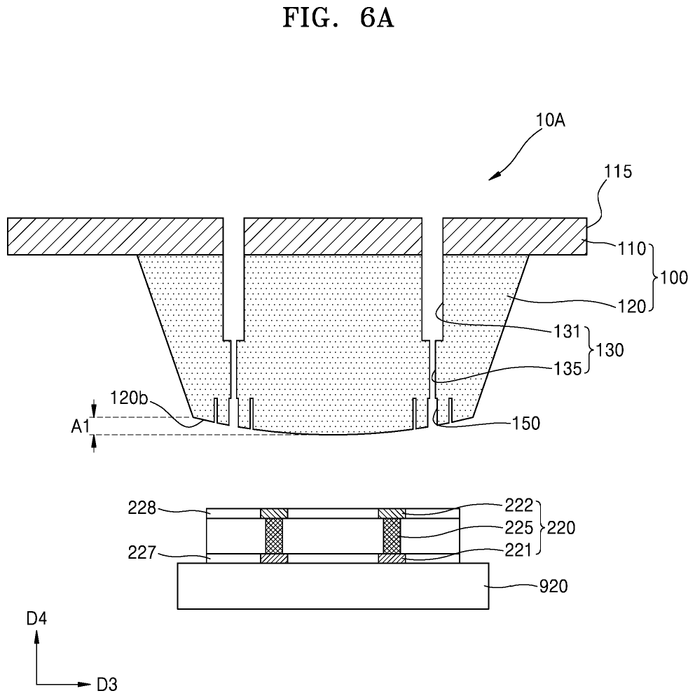

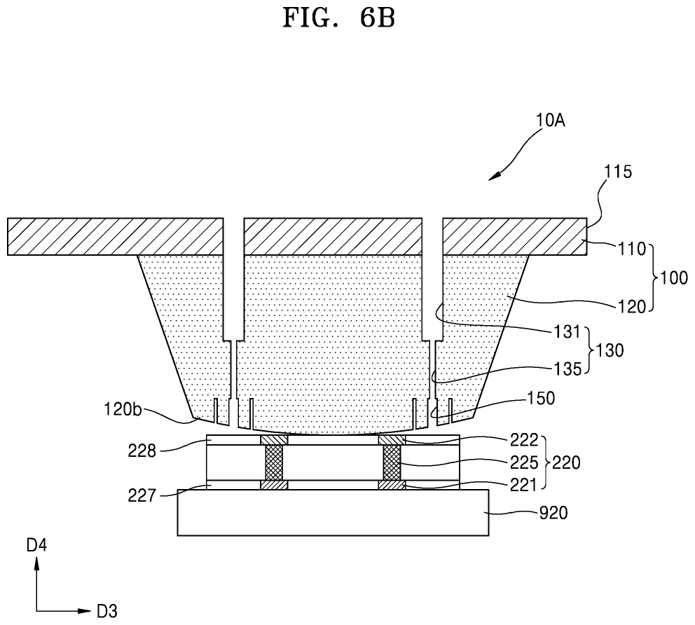

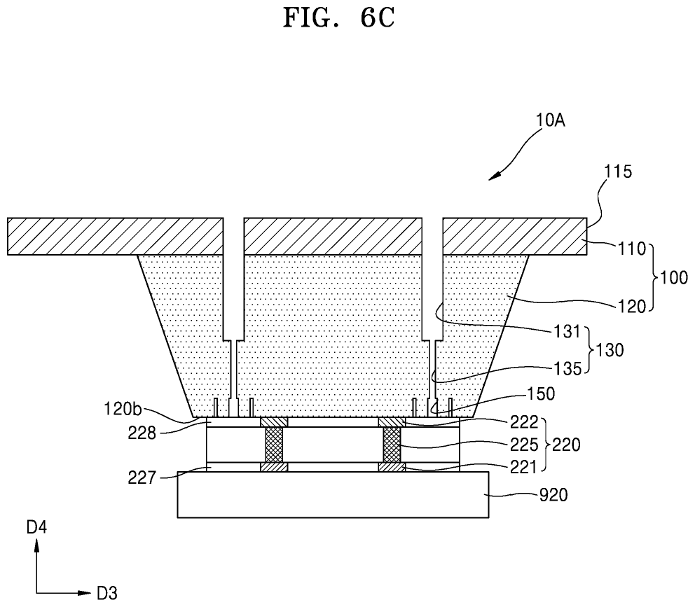

FIGS. 6A to 6C are diagrams for explaining a semiconductor package manufacturing method according to some embodiments. Hereinafter, descriptions that are substantially the same as those previously given are omitted.

Referring to FIG. 6A, the second semiconductor chip 220 may be provided on the second stage 920. A semiconductor package manufacturing apparatus 10A may be provided on the second semiconductor chip 220. The arrangement adjustment of the second semiconductor chip 220 and the bonding head 100 may be the same as described with reference to FIG. 5B. However, the semiconductor package manufacturing apparatus 10A described with reference to FIG. 3 may be used. The lower surface 120b of the lower bonding head 120 may have a downward convex shape.

Referring to FIG. 6B, the semiconductor package manufacturing apparatus 10A may move downward toward the second semiconductor chip 220. Since the lower surface 120b of the lower bonding head 120 has a downward convex shape, the center area of the lower surface 120b of the lower bonding head 120 may be in contact with the upper surface of the second semiconductor chip 220, and the edge area of the lower surface 120b of the lower bonding head 120 may be spaced apart from the upper surface of the second semiconductor chip 220.

Referring to FIGS. 6B and 6C in turn, vacuum pressure may be applied to the vacuum hole 130 and the adsorption trench 150 while the semiconductor package manufacturing apparatus 10A moves downward or after the semiconductor package manufacturing apparatus 10A moves downward. The suction force may be applied to the upper surface of the second semiconductor chip 220 by the vacuum pressure. Since the lower bonding head 120 has a modulus of 2.625 MPa or more, the shape of the lower surface 120b of the lower bonding head 120 may be deformed by the vacuum pressure and suction force. For example, as shown in FIG. 6C, the edge area of the lower surface 120b of the lower bonding head 120 may be provided at substantially the same level as the center area of the lower surface 120b of the lower bonding head 120. The edge area of the lower surface 120b of the lower bonding head 120 may contact the upper surface of the second semiconductor chip 220. Since the lower bonding head 120 has a modulus of 5 MPa or less, the shape of the lower bonding head 120 may be prevented from being excessively deformed.

According to some embodiments, after the center area of the lower bonding head 120 first contacts the second semiconductor chip 220 as shown in FIG. 6B, the shape of the lower surface 120b of the lower bonding head 120 may be deformed as shown in FIG. 6C. Afterwards, the edge area of the lower surface 120b of the lower bonding head 120 may contact the second semiconductor chip 220. Accordingly, the suction force generated by the adsorption trench 150 may be gradually applied to the second semiconductor chip 220. The adsorption trench 150 may further prevent pressure from being concentrated on a portion of the second semiconductor chip 220. Accordingly, deformation of the second semiconductor chip 220 may be further prevented, thereby maintaining the good shape of the second semiconductor chip 220. The semiconductor package manufacturing process may have a high yield.

As previously described, since the level difference (e.g., level difference A1 in FIGS. 4 and 6A) between the lowermost and uppermost parts of the lower surface 120b of the lower bonding head 120 is about 50 μm to about 150 μm, damage to the second semiconductor chip 220 due to pressure may be prevented, and the second semiconductor chip 220 may be strongly suctioned to the lower bonding head 120.

The semiconductor package manufacturing apparatus 10A may move together with the second semiconductor chip 220. The second semiconductor chip 220 may be separated from the second stage 920.

Referring again to FIG. 5D, the second semiconductor chip 220 may be provided on the first semiconductor chip 210. Afterwards, the second semiconductor chip 220 may be stacked on the first semiconductor chip 210. The first bonding process may be performed to bond the second semiconductor chip 220 to the first semiconductor chip 210. However, the above processes may be performed using the semiconductor package manufacturing apparatus 10A of FIG. 3 instead of the semiconductor package manufacturing apparatus 10 of FIG. 5D.

The first process and the stacking of the second semiconductor chip 220 described with reference to FIG. 5F may be repeatedly performed to manufacture the chip stack CS. However, the semiconductor package manufacturing apparatus 10A of FIG. 3 may be used for the first bonding process and the stacking of the second semiconductor chip 220. The second bonding process may be further performed on the first semiconductor chip 210 and the second semiconductor chips 220, but is not limited thereto.

FIGS. 7A to 7E are diagrams for explaining a semiconductor package manufacturing method according to some embodiments. Hereinafter, descriptions that are substantially the same as those previously given are omitted.

Referring to FIG. 7A, the second semiconductor chip 220 may be provided on the second stage 920. The semiconductor package manufacturing apparatus 10B described in of FIG. 4 may be provided on the second semiconductor chip 220. The lower surface 120b of the lower bonding head 120 may be relatively flat.

Referring to FIG. 7B, as pneumatic pressure is applied to the air hole 140, the lower surface 120b of the lower bonding head 120 may have a downward convex shape. For example, the center area of the lower surface 120b of the lower bonding head 120 may move downward due to pneumatic pressure applied to the air hole 140. Accordingly, the center area of the lower surface 120b of the lower bonding head 120 may be provided at a lower level than a level of the edge area of the lower surface 120b of the lower bonding head 120. By adjusting the strength of the pneumatic pressure, a level difference A1 between the lowermost and uppermost parts of the lower surface 120b of the lower bonding head 120 may be about 50 μm to about 150 μm. The lowermost part of the lower surface 120b of the lower bonding head 120 may be provided on the center area of the lower bonding head 120. The uppermost part of the lower surface 120b of the lower bonding head 120 may be provided on the edge area of the lower bonding head 120.

Referring to FIG. 7C, the semiconductor package manufacturing apparatus 10B may move downward toward the second semiconductor chip 220. Since the lower surface 120b of the lower bonding head 120 has a downward convex shape, the center area of the lower surface 120b of the lower bonding head 120 may be in contact with the upper surface of the second semiconductor chip 220, and the edge area of the lower surface 120b of the lower bonding head 120 may be spaced apart from the upper surface of the second semiconductor chip 220.

Referring to FIGS. 7C and 7D in turn, vacuum pressure may be applied to the adsorption trench 150 through the vacuum hole 130 while the semiconductor package manufacturing apparatus 10B moves downward or after the semiconductor package manufacturing apparatus 10B moves downward. Since the lower bonding head 120 has a modulus of 2.625 MPa or more, the shape of the lower surface 120b of the lower bonding head 120 may be deformed again. For example, the edge area of the lower surface 120b of the lower bonding head 120 may be provided at substantially the same level as a level of the center area of the lower surface 120b of the lower bonding head 120. The edge area of the lower surface 120b of the lower bonding head 120 may contact the upper surface of the second semiconductor chip 220. Since the lower bonding head 120 has a modulus of 5 MPa or less, the shape of the lower bonding head 120 may be prevented from being excessively deformed.

According to some embodiments, after the center area of the lower bonding head 120 first contacts the second semiconductor chip 220 as shown in FIG. 7C, the shape of the lower surface 120b of the lower bonding head 120 may be deformed as shown in FIG. 7D. Afterwards, the lower surface 120b of the lower bonding head 120 may contact the second semiconductor chip 220. Accordingly, the suction force generated by the adsorption trench 150 may be gradually applied to the second semiconductor chip 220. The pressure may be prevented from concentrating on a portion of the second semiconductor chip 220. The shape of the second semiconductor chip 220 may be well maintained.

Referring to FIG. 7E, the second semiconductor chip 220 may be provided on the first semiconductor chip 210 by moving the semiconductor package manufacturing apparatus 10B. The semiconductor package manufacturing apparatus 10B may move downward, and the second semiconductor chip 220 may be stacked on the first semiconductor chip 210. The first bonding process using the semiconductor package manufacturing apparatus 10B may be performed to bond the second semiconductor chip 220 with the first semiconductor chip 210.

As shown in FIG. 7B, since the level difference A1 between the lowermost and uppermost parts of the lower surface 120b of the lower bonding head 120 is about 50 μm to about 150 μm when pneumatic pressure is applied to the air hole 140, the damage to the second semiconductor chip 220 due to pressure during the first bonding process of FIG. 7E may be prevented, and the second semiconductor chip 220 may be strongly suctioned to the lower bonding head 120.

Referring again to FIG. 5F, the first process and the stacking of the second semiconductor chip 220 may be repeatedly performed to manufacture the chip stack CS. At this time, the semiconductor package manufacturing apparatus 10B of FIG. 4 may be used. Manufacturing the chip stack CS may further include performing the second bonding process on the first semiconductor chip 210 and the second semiconductor chips 220, but is not limited thereto.

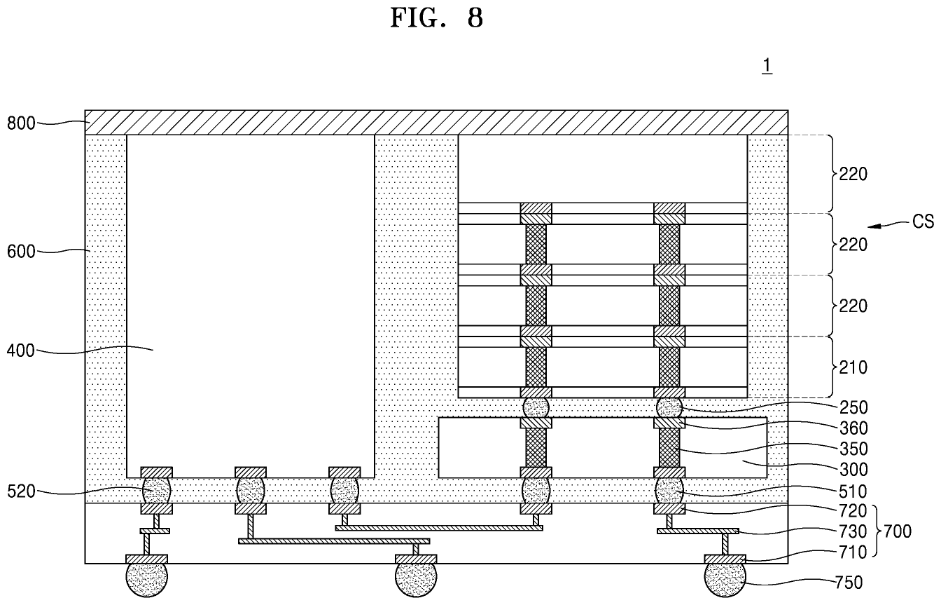

FIG. 8 is a diagram of a semiconductor package according to some embodiments.

Referring to FIG. 8, a semiconductor package 1 may include an interposer substrate 700, solder balls 750, a lower semiconductor chip 300, a chip stack CS, a semiconductor device 400, and a molding film 600. The interposer substrate 700 may include lower metal pads 710, upper metal pads 720, and metal wires 730. The lower metal pads 710 and the upper metal pads 720 may be provided on the lower and upper surfaces of the interposer substrate 700, respectively. The metal wires 730 may be provided within the interposer substrate 700. The upper metal pads 720 may be connected to the lower metal pads 710 by the metal wires 730. Being electrically connected to the interposer substrate 700 may refer to being electrically connected to at least one of the metal wires 730. The lower metal pads 710, the upper metal pads 720, and the metal wires 730 may include metal such as copper, aluminum, tungsten, and/or titanium.

The solder balls 750 may be provided on the lower surface of the interposer substrate 700 to be connected to the lower metal pads 710. The solder balls 750 may include solder material.

The lower semiconductor chip 300 may be provided on an upper surface of the interposer substrate 700. The lower semiconductor chip 300 may include a logic chip. The lower semiconductor chip 300 may include third integrated circuits, conductive pads 360, and lower through vias 350. The third integrated circuits may be provided within the lower semiconductor chip 300. The lower through vias 350 may pass through the lower semiconductor chip 300 to be electrically connected to the third integrated circuits. The conductive pads 360 may be provided on the upper surface of the lower semiconductor chip 300, and may be connected to the lower through vias 350.

The first lower bumps 510 may be positioned between the interposer substrate 700 and the lower semiconductor chip 300, and may be connected to the interposer substrate 700 and the lower semiconductor chip 300. The first lower bumps 510 may include solder material.

The chip stack CS may be mounted on the lower semiconductor chip 300. The chip stack CS may be as described with reference to FIG. 5F, and may include the first semiconductor chip 210 and the second semiconductor chips 220. The number of second semiconductor chips 220 included in the chip stack CS may vary. Mounting the chip stack CS on the lower semiconductor chip 300 may include connecting the plurality of solder bumps 250 to the conductive pads 360. Accordingly, the first semiconductor chip 210 and the second semiconductor chip 220 may be electrically connected to the lower semiconductor chip 300. The type of the first semiconductor chip 210 and the second semiconductor chips 220 may be different from the type of the lower semiconductor chip 300.

The semiconductor device 400 may be mounted on the upper surface of the interposer substrate 700. The semiconductor device 400 may be laterally spaced apart from the lower semiconductor chip 300 and the chip stack CS. The semiconductor device 400 may include a semiconductor chip. For example, the semiconductor device 400 may include a logic chip, a buffer chip, or a system-on-chip (SOC). The semiconductor device 400 may be, for example, an application specific integrated circuit (ASIC) chip or an application processor (AP) chip. The ASIC chip may include an ASIC. The semiconductor device 400 may include a central processing unit (CPU) or a graphics processing unit (GPU).

The second lower bumps 520 may be positioned between the interposer substrate 700 and the semiconductor device 400, and may be connected to the interposer substrate 700 and the semiconductor device 400. The second lower bumps 520 may include solder material.

The molding film 600 may be disposed on the interposer substrate 700 to cover sidewalls of the lower semiconductor chip 300, sidewalls of the chip stack CS, and sidewalls of the semiconductor device 400. The molding film 600 may expose an upper surface of the second uppermost semiconductor chip 220 and an upper surface of the semiconductor device 400. As another example, the molding film 600 may further cover the upper surface of the second uppermost semiconductor chip 220 and the upper surface of the semiconductor device 400. The molding film 600 may include an insulating polymer such as an epoxy-based polymer.

The semiconductor package 1 may further include a heat sink 800. The heat sink 800 may be disposed on at least one from among the upper surface of the semiconductor device 400 and the upper surface of the second uppermost semiconductor chip 220. The heat sink 800 may further cover the upper surface of the molding film 600. The heat sink 800 may further extend onto sidewalls of the molding film 600. The heat sink 800 may include a heat slug or a heat sink. The heat sink 800 may include a material with high thermal conductivity, such as metal.

Some embodiments may be combined with each other. At least two from among an embodiment of FIGS. 1A to 1C, an embodiment of FIG. 2A, an embodiment of FIG. 2B, an embodiment of FIG. 2C, an embodiment of FIG. 2D, an embodiment of FIG. 2E, an embodiment of FIG. 2F, an embodiment of FIG. 2G, an embodiment of FIG. 2H, an embodiment of FIG. 2I, an embodiment of FIG. 3, and an embodiment of FIG. 4 may be combined with each other.

While non-limiting example embodiments have been particularly shown and described herein, it will be understood that various changes in form and details may be made without departing from the spirit and scope of the present disclosure.

What is claimed is:

1. A semiconductor package manufacturing apparatus comprising:
a bonding head comprising:
at least one vacuum hole; and
at least one adsorption trench in a lower surface of the bonding head and connected to the at least one vacuum hole,
wherein a lower part of the bonding head comprises:
at least one first portion; and
a second portion spaced apart from the at least one first portion and surrounding the at least one first portion in a plan view,
wherein the at least one adsorption trench is defined by and between the at least one first portion and the second portion, and
wherein at least a portion of an inner surface of the at least one adsorption trench and at least a portion of an outer surface of the at least one adsorption trench are curved in the plan view.

2. The semiconductor package manufacturing apparatus of claim 1, wherein the inner surface of the at least one adsorption trench is circular or oval in the plan view.

3. The semiconductor package manufacturing apparatus of claim 1, wherein the at least one first portion is a plurality of first portions, and
wherein the at least one adsorption trench is defined by and between adjacent first portions from among the plurality of first portions of the bonding head.

4. The semiconductor package manufacturing apparatus of claim 1, wherein the bonding head further comprises an air hole spaced laterally from the at least one vacuum hole,
wherein the air hole is spaced apart from the lower surface of the bonding head and overlaps a center area of the lower surface of the bonding head in the plan view, and
wherein the air hole is configured to receive pneumatic pressure.

5. The semiconductor package manufacturing apparatus of claim 1, wherein the lower surface of the bonding head comprises:
a center area; and
an edge area surrounding the center area in the plan view, and
wherein the center area is provided at a lower level than a level of the edge area.

6. The semiconductor package manufacturing apparatus of claim 5, wherein a level difference between the center area and the edge area of the lower surface of the bonding head is 50 μm to 150 μm.

7. The semiconductor package manufacturing apparatus of claim 1, wherein each of the at least one vacuum hole comprises:
an upper vacuum hole having a first diameter; and
a lower vacuum hole between the upper vacuum hole and the at least one adsorption trench and having a second diameter that is less than the first diameter.

8. The semiconductor package manufacturing apparatus of claim 7, wherein a portion of the at least one adsorption trench overlaps the lower vacuum hole in the plan view, and
wherein another portion of the at least one adsorption trench is spaced apart from the lower vacuum hole in the plan view.

9. The semiconductor package manufacturing apparatus of claim 1, wherein the at least one vacuum hole is a plurality of vacuum holes,
wherein the at least one adsorption trench is a plurality of adsorption trenches, and
wherein the plurality of vacuum holes and the plurality of adsorption trenches overlap an edge area of the lower surface of the bonding head in the plan view.

10. The semiconductor package manufacturing apparatus of claim 1, wherein a gap between the inner surface and the outer surface of the at least one adsorption trench is 50 μm to 150 μm.

11. A semiconductor chip bonding apparatus comprising:
a bonding head comprising:
an upper bonding head that comprises a placement guide portion;
a lower bonding head on a lower surface of the upper bonding head and having a smaller width than a width of the upper bonding head;
a vacuum hole passing through the upper bonding head and a portion of the lower bonding head; and
an adsorption trench in a lower surface of the lower bonding head and connected to the vacuum hole,
wherein at least a portion of an outer surface of the adsorption trench has a curved shape in a plan view, and
wherein the adsorption trench is in an edge area of the lower surface of the lower bonding head.

12. The semiconductor chip bonding apparatus of claim 11, wherein the placement guide portion is configured to provide information about direction or position of the bonding head.

13. The semiconductor chip bonding apparatus of claim 12, wherein the placement guide portion comprises a notch portion, and
wherein opposite ends of the notch portion are respectively connected to two sides of the upper bonding head in the plan view.

14. The semiconductor chip bonding apparatus of claim 11, wherein a lower part of the bonding head comprises:
a first portion having a circular or oval shape; and
a second portion spaced apart from the first portion in the plan view,
wherein the adsorption trench is defined by and between the first portion and the second portion, and an inner surface of the adsorption trench has a curved shape.

15. The semiconductor chip bonding apparatus of claim 11, wherein the bonding head further comprises an air hole,
wherein the air hole is spaced apart from the lower surface of the bonding head and the adsorption trench, and
wherein the air hole is configured to receive pneumatic pressure.

16. The semiconductor chip bonding apparatus of claim 11, wherein a center area of the lower surface of the bonding head is at a lower level than a level of the edge area of the lower surface of the bonding head.

17. A semiconductor package manufacturing apparatus comprising:
a bonding head comprising:
an upper bonding head comprising a notch portion;
a lower bonding head on a lower surface of the upper bonding head, having a smaller width than a width of the upper bonding head, and comprising a material that is different from a material of the upper bonding head;
a vacuum hole passing through the upper bonding head and extending into the lower bonding head; and
an adsorption trench connected to the vacuum hole and passing through a lower surface of the lower bonding head,
wherein the vacuum hole comprises:
an upper vacuum hole having a first diameter; and
a lower vacuum hole between the upper vacuum hole and the adsorption trench and having a second diameter that is less than the first diameter,
wherein a lower part of the lower bonding head comprises:
a first portion; and
a second portion spaced apart from the first portion and surrounding the first portion in a plan view, and
wherein the adsorption trench is defined by and between the first portion and the second portion, and an inner surface and an outer surface of the adsorption trench have a curved shape.

18. The semiconductor package manufacturing apparatus of claim 17, wherein the upper bonding head comprises metal or metal alloy, and
the lower bonding head comprises silicone rubber and has a modulus of 2.625 MPa to 5 MPa.

19. The semiconductor package manufacturing apparatus of claim 17, wherein the adsorption trench has a closed loop or donut shape in the plan view.

20. The semiconductor package manufacturing apparatus of claim 17, wherein the upper bonding head comprises a placement guide portion that is configured to provide information about direction or position of the bonding head.
